(19) United States
(12) Patent Application Publication
(10) Pub. No.: US 2003/0171001 A1
(43) Pub. Date: Sep. 11, 2003

(54) Method of manufacturing semiconductor devices

(76) Inventor: Masahide Shinohara, Tokyo (JP)

Correspondence Address: KATTEN MUCHIN ZAVIS ROSENMAN, 575 MADISON AVENUE, NEW YORK, NY, 10022-2585, US

(21) Appl. No.: 10/094,015

(22) Filed: Mar. 8, 2002

(51) Int. Cl. H01L 21/31

(52) U.S. Cl. 438/758

(57) ABSTRACT

A semiconductor device manufacturing method by which an organic resin film is formed on a semiconductor substrate in which integrated circuit elements and a wiring pattern have been formed and the entire circuit is sealed in a mold resin, includes a step of using an exposure mask having at least a pattern finer than the resolution limit of the organic resin to form a plurality of cavities on the surface of the organic resin film.

### BACKGROUND OF THE INVENTION

1. Field of the Invention

The present invention relates to a semiconductor device manufacturing method, and more particularly to a semiconductor device manufacturing method for promoting adhesion between a polyimide film formed on the semiconductor device and the mold resin in which the semiconductor device is sealed.

2. Description of the Prior Art

In recent years, as the integration scale of semiconductor devices increases, the semiconductor devices are increasingly becoming susceptible to temperature changes, which produce thermal stresses between passivation films formed on the devices and the mold resin in which they are sealed.

Therefore, a structure has been suggested in which a polyimide film is formed as a buffer layer between the mold resin and the passivation film to relieve the stress.

There are two known methods of fabricating a semiconductor device with this structure: a first method in which each of the passivation film and polyimide film is patterned by lithography, and a second method in which the polyimide film is patterned first, then the passivation film is patterned by using the polyimide film as a mask.

The latter method will now be described with reference to FIGS. 6 and 7. This method has been disclosed in JP-A-08107/1995 and other patent documents.

First an insulating film 32 is formed on a semiconductor substrate 31 in which integrated circuit elements have been formed; then a metal film, more specifically, an alloy film 33 made of a type of Al alloy, such as an Al—Si—Cu alloy, for example, is formed on the insulating film 32 by sputtering. One practical thickness of the alloy film is 500 nm. (FIG. 6A) Next, the alloy film 33 is coated with a photoresist by a spin coating method and an exposure and development sequence is carried out to forma resist pattern. Then, the resist pattern is used as a mask to etch the alloy film 33 by reactive ion etching (RIE) utilizing a chlorine-based gas to form wiring 34. (FIG. 6B)

Next, a passivation film 35, such as a silicon nitride (Si₃N₄) film (abbreviated as an SN film below), is formed on the wiring 34 and the insulating film 32 by using a chemical vapor deposition (CVD) technique. One practical thickness of the SN film is 1000 nm. (FIG. 6C) Next, a photoresist polyimide precursor solution is dispensed onto the SN film 35 and spin-coated to form a polyimide film 36 with a desired thickness, such as 20000 nm. (FIG. 6D)

Next, the polyimide film 36 is exposed and developed to form a hole 37 that reaches the SN film 35 at a desired position on the polyimide film 36. (FIG. 7A)

Next, heat treatment 38 is carried out under optimum conditions, at a temperature of 300 to 400° C. for 60 to 120 minutes, to cause an imidization reaction to cure the polyimide film 36 to a polyimide film 36′. (FIG. 7B)

Next, the cured polyimide film 36′ is used as a mask to etch the SN film 35 by RIE utilizing a mixed fluorine gas, such as CF₄/O₂ mixed gas to form a bonding pad (an external lead electrode) 39 on a part of the wiring 34.

After that, each chip is separated from the wafer, a lead frame is bonded to either the upper or bottom surface of the chip, the bonding pad 39 is electrically connected to a lead of the lead frame, and the entire circuit is sealed in an epoxy resin mold.

The first method described above uses lithography in each film forming process, so entails the problem that the number of processes increases and accordingly the manufacturing cost. Increasing the number of processes is not desirable under present conditions, in which shorter manufacturing times are needed.

In addition, the second method of the prior art uses the polyimide film 36′ formed on the SN film 35 as a mask to etch the SN film 35 to form the bonding pad 39 on a part of the wiring 34, thereby enabling a reduction of the number of processes and the manufacturing cost, but this raises a problem in that adhesion cannot be improved because only the portion of the bonding pad 39 under the opening is available and the surface area is limited by the chip size.

### BRIEF SUMMARY OF THE INVENTION

### OBJECT OF THE INVENTION

It is accordingly an object of the present invention to provide a method of manufacturing semiconductor devices by which adhesion between a polyimide film or another applicable organic resin film and a mold resin in which the entire circuit is sealed can be promoted.

### SUMMARY OF THE INVENTION

A semiconductor device manufacturing method by which an organic resin film is formed on a semiconductor substrate in which integrated circuit elements and a wiring pattern have been formed and the entire circuit is sealed in a mold resin, uses an exposure mask having a pattern finer than the resolution limit of the organic resin film on a part thereof to form cavities on the surface of the organic resin film.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIGS. 1A to 1D are cross-sectional views showing semiconductor device manufacturing steps according to a first embodiment of the present invention;

FIGS. 2A to 2C are cross-sectional views showing semiconductor device manufacturing steps according to the first embodiment of the present invention;

FIGS. 3A to 3D are cross-sectional views showing semiconductor device manufacturing steps according to a second embodiment of the present invention;

FIGS. 4A to 4C are cross-sectional views showing semiconductor device manufacturing steps according to the second embodiment of the present invention;

FIG. 5 is an explanatory diagram showing a method of measuring shearing strength;

FIGS. 6A to 6D are cross-sectional views showing semiconductor device manufacturing steps according to the prior art; and

FIGS. 7A to 7C are cross-sectional views showing semiconductor device manufacturing steps according to the prior art.

### DETAILED DESCRIPTION OF THE INVENTION

Embodiments of a semiconductor device and a method of manufacturing the same will be described with reference to the attached drawings.

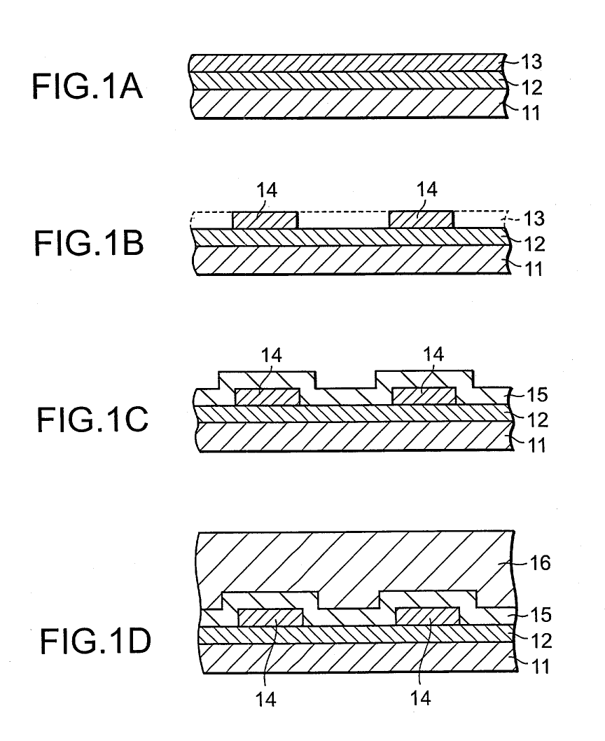

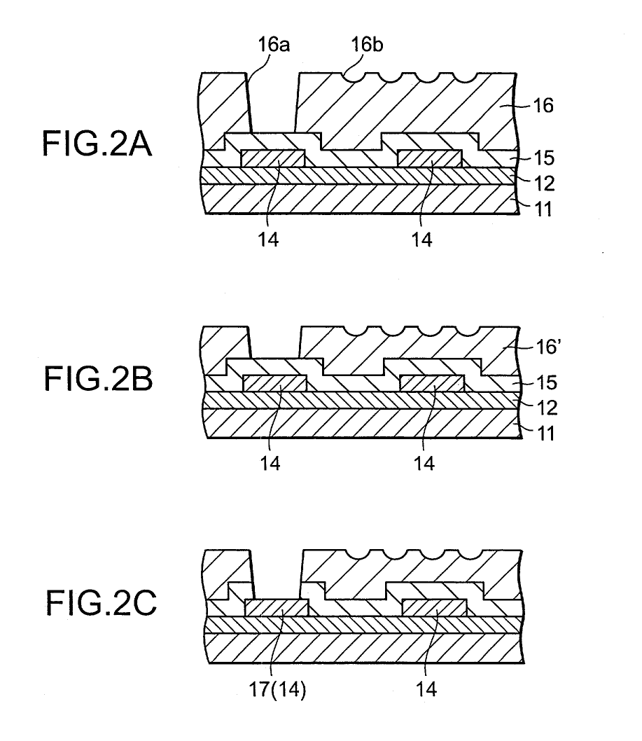

FIGS. 1 and 2 are cross-sectional views showing semiconductor device manufacturing steps according to a first embodiment of the present invention.

The manufacturing steps of the semiconductor device will now be described.

First an insulating film 12 is formed on a semiconductor substrate 11 in which integrated circuit elements have been formed; then a metal film, more specifically, an alloy film 13 made of a type of Al alloy, such as an Al—Si—Cu alloy, for example, with a thickness of 500 nm is formed on the insulating film 12 by sputtering or evaporation. (FIG. 1A) Next, the Al—Si—Cu alloy film 13 is coated with a photoresist and exposed and developed to form a resist pattern. Then, the resist pattern is used as a mask to etch the Al—Si—Cu alloy film 13 by RIE utilizing a chlorine-based gas to form a wiring pattern 14 made of an Al—Si—Cu alloy. (FIG. 1B) Next, on the wiring pattern 14 and the insulating film 12, an Si₃N₄ film (SN film) 15 with a thickness of 1000 nm that becomes a passivation film is formed by using a chemical vapor deposition (CVD) method. (FIG. 1C)

Next, a photoresist polyimide precursor solution is dispensed onto the SN film 15 and spin-coated on the entire surface thereof to form a polyimide film (an organic resin film) 16 with a desired thickness, such as 20000 nm. (FIG. 1D)

Then, the polyimide film 16 is subject to an exposure and development process to form patterns of bonding pads and other applicable patterns. In the region other than the bonding pad and other pattern portions on a mask used in this process, a pattern finer than the resolution limit of polyimide, such as a 1 sq μm void pattern, is formed.

If this type of mask is used for the exposure and development process, a hole 16a is formed at the bonding pad pattern portion, but no holes reaching the SN film 15 are formed at the 1 sq μm void pattern portions, and cavities are formed instead, on the surface of the polyimide film 16. This forms a plurality of fine cavities 16b 1 sq μm in. size and 0.2 μm deep on the surface of the polyimide film 16 (FIG. 2A).

Using a mask of a hole pattern 1 sq μm or more in size can produce a cavity 1 to 3 sq μm in size and 0.2 to 0.3 μm deep.

Although this embodiment provides the plurality of cavities 16b on the surface of the polyimide film 16 by forming patterns finer than the resolution limit of polyimide on the inner part of a chip pattern on the mask, another embodiment may form the plurality of cavities 16b on the surface of the polyimide film 16 by creating applicable patterns on portions other than the chip pattern portion on the mask and using the influence of flare (leakage of light) on the exposure.

In this case, the resultant cavities will be 100 to 500 sq μm in size and 0.1 to 1.0 μm deep.

After the plurality of cavities 16b are formed on the surface of the polyimide film 16, an imidization reaction is caused under conditions, at a temperature of 300 to 400°C. for 30 to 120 minutes, to cure the polyimide film 16 to a polyimide film 16′ (FIG. 2B)

Then, the cured polyimide film 16′ is used as a mask to etch the SN film 15 by RIE utilizing a mixed fluorine gas, such as a CF₄/O₂ mixed gas to form a bonding pad (an external lead electrode) 17 on a part of the wiring 14. After that, oxide plasma ashing processing on the surface of the semiconductor substrate is carried out.

Surface process of the semiconductor substrate is carried out by using a type of chemical that does not damage the polyimide film 16′, such as ethanol and a resist developer. (FIG. 2C) Then, each chip is separated from the wafer, a lead frame is bonded to either the upper or bottom surface of the chip, the bonding pad 17 is electrically connected to a lead of the lead frame, and the entire circuit is sealed in an epoxy resin mold.

The method described above can provide a semiconductor device of this embodiment.

The method of manufacturing a semiconductor device of this embodiment can increase the surface area of the polyimide film 16′ because a plurality of fine cavities 16b are formed thereon, and accordingly enable the improvement of adhesion with the mold resin, thereby making it possible to improve reliability of the semiconductor device.

The semiconductor device manufacturing method according to this embodiment forms patterns finer than the resolution limit of polyimide on a mask used to expose and develop the polyimide film 16, so the exposure and development process using this mask enables concurrent formation of the hole 16a at the bonding pad pattern portion and the plurality of fine cavities 16b on the surface of the polyimide film 16. Therefore, it is not necessary to provide extra processes for forming the plurality of cavities 16b and the plurality of fine cavities 16b can be formed on the surface of the polyimide film 16 easily without changing the pattern shapes of the mask.

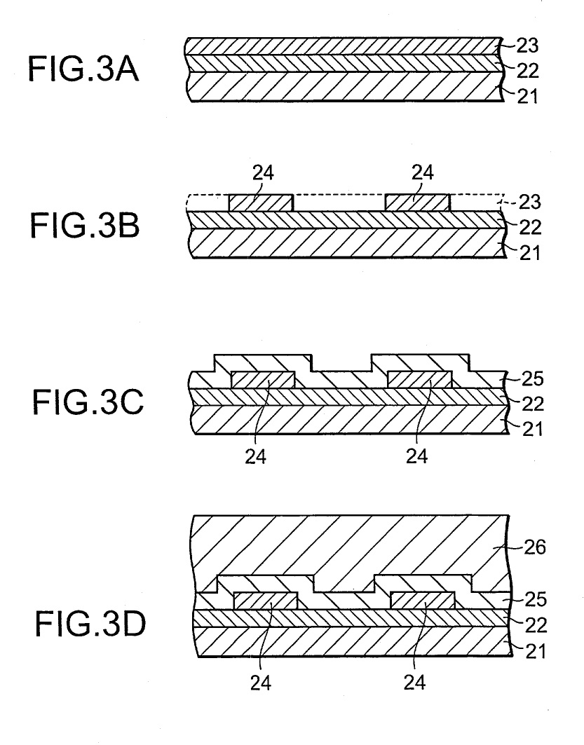

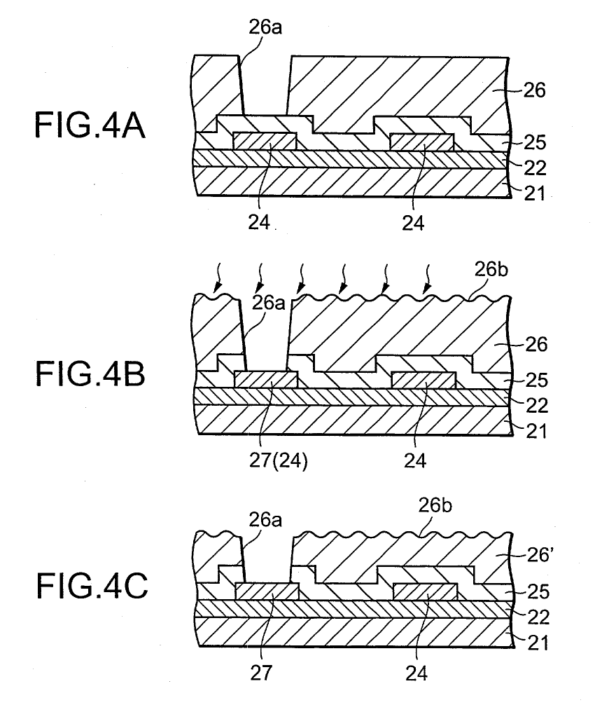

FIGS. 3 and 4 are cross sectional view showing semiconductor device manufacturing steps according to a second embodiment of the present invention.

The semiconductor device manufacturing steps will now be described.

First an insulating film 22 is formed on a semiconductor substrate 21 in which integrated circuit elements have been formed. Then, a metal film, more specifically, an alloy film 23 made of a type of Al alloy, such as an Al—Si—Cu alloy, with a thickness of 500 nm is formed on the insulating film 22 by sputtering or evaporation. (FIG. 3A)

Next, the Al—Si—Cu alloy film 13 is coated with a photoresist and exposed and developed to form a resist pattern; then, the resist pattern is used as a mask to etch the Al—Si—Cu alloy film 23 to form a wiring pattern 24 made of an Al—Si—Cu alloy by RIE utilizing a chlorine-based gas. (FIG. 3B) Next, on the wiring pattern 24 and the insulating film 22, a silicon nitride (Si₃N₄) film (an SN film) 25 with a thickness of 1000 nm that becomes a passivation film is formed by a CVD method. (FIG. 3C)

A photoresist polyimide precursor solution is dispensed onto the SN film 25 and spin-coated on the entire surface of the semiconductor substrate 21 to form a polyimide film (an organic resin film) 26 of a desired thickness, such as 20000 nm. (FIG. 3D)

Then, the polyimide film 26 is exposed and developed to form a pattern of a hole 26a at the portion of a bonding pad 27. (FIG. 4A)

The polyimide film 26 is used as a mask to etch the SN film 25 to form the bonding pad (external lead electrode) 27 on a part of the wiring 24 by RIE utilizing a mixed fluorine gas, such as a CF₄/O₂ mixed gas. The mixed fluorine gas used in this process also changes the property of the surface of the polyimide film 26 and a plurality of fine cavities 26b are formed. (FIG. 4B)

After that, oxide plasma ashing processing of the surface of the semiconductor substrate is carried out.

Next, an imidization reaction of the polyimide film 26 is caused for curing under conditions, at a temperature of 300 to 400° C. for 30 to 120 minutes. This can produce a polyimide film 26′ on the surface of which the plurality of fine cavities 26a have been formed. (FIG. 4C)

Then, each chip is separated from the wafer, a lead frame is bonded to either the upper or bottom surface of the chip, the bonding pad 27 is electrically connected to a lead of the lead frame, and the entire circuit is sealed in an epoxy resin mold.

The method described above can provide a semiconductor device according to this embodiment.

The semiconductor device manufacturing method of this embodiment can increase the surface area of the polyimide film 26′ because the plurality of fine cavities 26b are formed on the surface of the polyimide film 26′, and accordingly improve adhesion with the mold resin, thereby making it possible to improve reliability of the semiconductor device.

According to the semiconductor device manufacturing method of this embodiment, when the polyimide film 26 is used as a mask to etch the SN film 25 to form the bonding pad 27, a mixed fluorine gas used for the etching also changes the property of the surface of the polyimide film 26, thereby enabling the plurality fine cavities 26b to be formed on the surface of the polyimide film 26 at the same time the hole 26a is formed at the bonding pad portion. Therefore, the plurality of fine cavities 26b can be formed on the surface of the polyimide film 26 easily without any extra step for forming them.

Table 1 shows the result of evaluating adhesion between a polyimide film and epoxy resin in a semiconductor device of the present invention and a semiconductor device of the prior art.

TABLE 1

| | After formation of sample | 48 hours after PCT |
|---|---|---|
| Embodiment 1 | 4.7 | 4.3 |
| Embodiment 2 | 4.9 | 4.1 |
| Prior art | 4.0 | 3.7 |

UNIT: kg/mm²

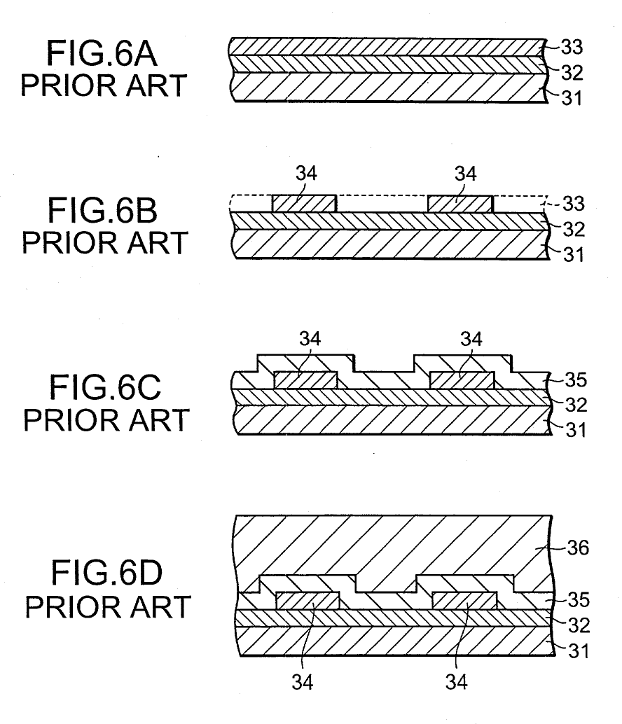

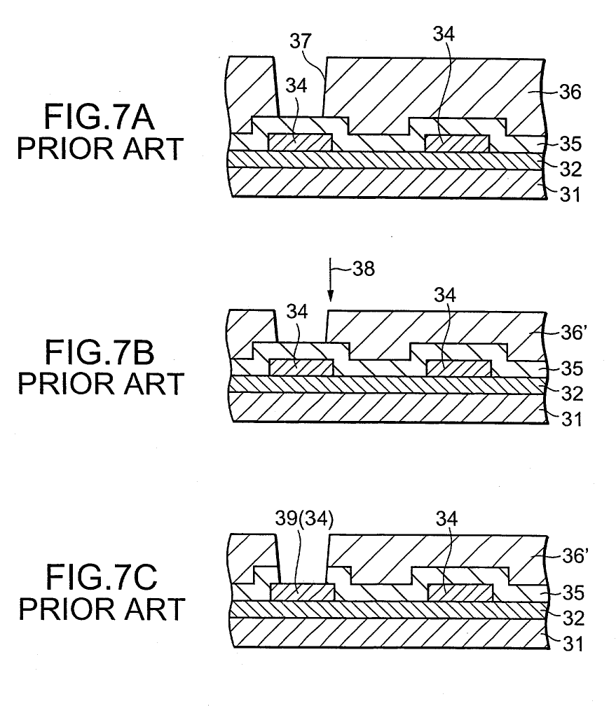

In Table 1, the entries of ‘Embodiment 1’, ‘Embodiment 2’ and ‘PRIOR ART’ indicate the results of adhesion evaluations for semiconductor devices that are obtained by the manufacturing method shown in FIGS. 1 and 2, FIGS. 3 and 4, and FIGS. 6 and 7, respectively, before and after pressure cooker tests (PCTs).

The PCT tests the durability under conditions of a high temperature and humidity. In this case, the devices have been left in a saturation mode of 125° C. and 1.4 kgf/cm² for 48 hours.

The adhesion is evaluated by a shear strength measuring method.

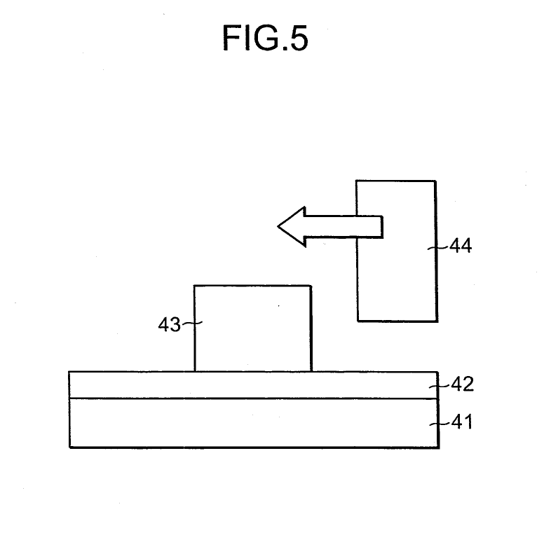

The shear strength measuring method will be described with reference to FIG. 5. A measuring sample was made by coating and curing polyimide resin on the semiconductor substrate 41 to form a polyimide film 42 and by forming a mold resin pole 43 the size of 2 mm² and 2 mm high on the polyimide film 42. The mold resin pole 43 is pressed in from the side with a forcing fixture 44 and the strength that causes peeling or damage of the mold resin pole 43 was measured.

It is clear from Table 1 that both the semiconductor devices of ‘Embodiment 1’ and ‘Embodiment 2’ have higher adhesion comparing to that obtained by ‘Prior art’.

Up to this point, the embodiments of a semiconductor device and a method of manufacturing the same according to the present invention have been described with reference to the attached drawings. It is further understood by those skilled in the art that the foregoing descriptions are preferred embodiments of the disclosed device and that various changes and modifications may be made in the invention without departing from the spirit and scope thereof.

The semiconductor device manufacturing method according to the present invention makes it possible to form a plurality of cavities on the surface of the organic resin film easily while other step is carried out, thereby eliminating the need for extra steps for forming the cavities.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A semiconductor device manufacturing method that forms an organic resin film on a semiconductor substrate in which integrated circuit elements and a wiring pattern are formed and seals the entire circuit in a mold resin, comprising a step of forming a plurality of cavities on the surface of the organic resin film by using an exposure mask on which at least a pattern finer than the resolution limit of the organic resin is formed.

2. A semiconductor device manufacturing method that forms an organic resin film on a semiconductor substrate in which integrated circuit elements and a wiring pattern are formed and seals the entire circuit in a mold resin, comprising steps of selectively removing the organic resin film to form an external lead electrode on a part of the wiring pattern and a plurality of cavities on the surface of the organic resin film at the same time, and curing the organic resin film thereafter.

3. The semiconductor device manufacturing method of claim 2, comprising the organic resin film that is a polyimide film, and steps of forming a plurality of cavities on the polyimide film, and then causing an imidization reaction of the polyimide film to be cured.

4. The semiconductor device manufacturing method of claim 1 or 2, wherein the plurality of cavities are 1 to 3 sq μm in size and 0.2 to 0.3 μm deep.

5. The semiconductor device manufacturing method of claim 1 or 2, wherein the plurality of cavities are 100 to 500 sq μm in size and 0.1 to 1.0 μm deep.
